(19) United States
(12) Patent Application Publication
(10) Pub. No.: US 2024/0369605 A1
(43) Pub. Date: Nov. 7, 2024

(54) POWER LEVEL DETECTION CIRCUIT AND TWO-STAGE POWER DOMAIN CIRCUIT

(71) Applicant: MEDIATEK INC., Hsinchu City (TW)

(72) Inventors: Jen-Hang YANG, Hsinchu City (TW); Ying-Chun WEI, Hsinchu City (TW)

(21) Appl. No.: 18/423,531

(22) Filed: Jan. 26, 2024

Related U.S. Application Data
(60) Provisional application No. 63/499,497, filed on May 2, 2023.

(51) Int. Cl. G01R 21/133; G01R 15/14

(52) U.S. Cl. CPC G01R 21/133; G01R 15/14

(57) ABSTRACT

A power level detection circuit is provided. The power level detection circuit includes a resistive circuit, a pull-up circuit, a pull-down circuit, and an output terminal. The resistive circuit is coupled between a first power terminal and a first node. The first terminal is coupled to a first supply voltage. The pull-up circuit is coupled between a second power terminal and a second node. The second power terminal is coupled to a second supply voltage. The pull-down circuit is coupled between the second node and a common ground. The output terminal is coupled to the second node and configured to output a detection signal. The pull-up circuit and the pull-down circuit are configured to control a time point that the detection signal starts to transition from a first level to a second level according to the first supply voltage and the second supply voltage.

### CROSS REFERENCE TO RELATED APPLICATIONS

This application claims the benefit of U.S. Provisional Application No. 63/499,497, filed May 2, 2023, the entirety of which is/are incorporated by reference herein.

### BACKGROUND OF THE INVENTION

### Field of the Invention

The invention relates to a power level detection circuit, and more particularly to a power level detection circuit for circuits in different power domains.

### Description of the Related Art

In a circuit with two power domains, a first stage circuit in a first power domain generates a signal at an output terminal of the first power domain and provides the generated signal to a second stage circuit in a second power domain. When the level of the supply voltage of the second power domain has been on a predetermined supply level (that is, the level of the supply voltage of the second power domain is on a predetermined high level) but the level of the supply voltage of the first power domain is still on a low level, the first stage circuit does not operate, and the output terminal is in an unknown state. The output terminal of the first stage circuit may induce high crowbar currents in the second stage circuit.

### BRIEF SUMMARY OF THE INVENTION

An exemplary embodiment of a power level detection circuit is provided. The power level detection circuit comprises a resistive circuit, a pull-up circuit, a pull-down circuit, and an output terminal. The resistive circuit is coupled between a first power terminal and a first node. The first terminal is coupled to a first supply voltage. The pull-up circuit is coupled between a second power terminal and a second node. The second power terminal is coupled to a second supply voltage. The pull-down circuit is coupled between the second node and a common ground. The output terminal is coupled to the second node and configured to output a detection signal. The pull-up circuit and the pull-down circuit are configured to control a time point that the detection signal starts to transition from a first level to a second level according to the first supply voltage and the second supply voltage.

An exemplary embodiment of a two-stage power domain circuit is provided. The two-stage power domain circuit comprises a first stage circuit, a second stage circuit, and a power level detection circuit. The first stage circuit operates in a first power domain. The first stage circuit is configured to receive an input signal and generate an intermediate signal. The second stage circuit operates in a second power domain. The second stage circuit is configured to receive the intermediate signal and generate an output signal. The power level detection circuit is configured to receive a first supply voltage of the first power domain and a second supply voltage of the second power domain and generate a first detection signal. The power level detection circuit is further configured to control a time point that the first detection signal starts to transition from a first level to a second level according to the first supply voltage and the second supply voltage.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 shows one exemplary embodiment of a two-stage power domain circuit;

FIG. 2 shows another exemplary embodiment of a two-stage power domain circuit;

FIG. 3 shows one exemplary embodiment of a power level detection circuit;

FIG. 4 shows a timing chart of main signals of a two-stage power domain circuit according to an exemplary embodiment;

FIG. 5 shows another exemplary embodiment of a power level detection circuit;

FIG. 6 shows another exemplary embodiment of a power level detection circuit;

FIG. 7 shows another exemplary embodiment of a power level detection circuit;

FIG. 8 shows an exemplary embodiment of layout of a power level detection circuit; and

FIG. 9 shows another exemplary embodiment of a two-stage power domain circuit.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

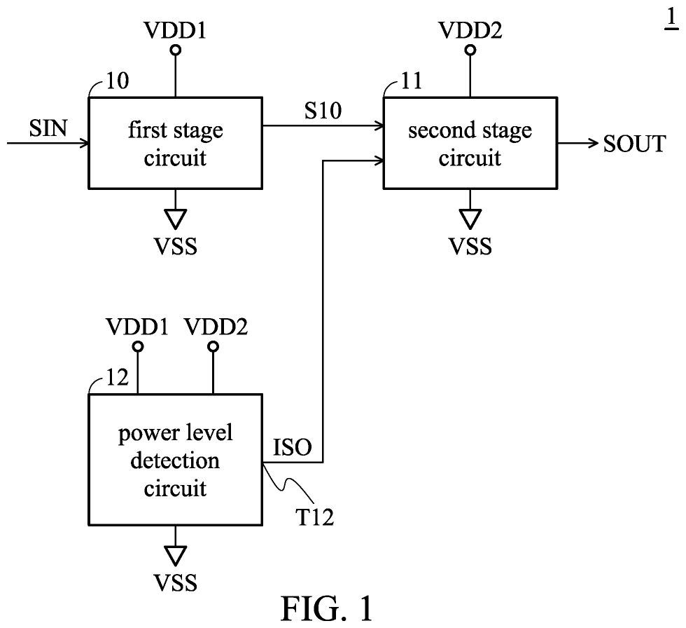

FIG. 1 shows an exemplary embodiment of a two-stage power domain circuit 1. Referring to FIG. 1, the two-stage power domain circuit 1 comprises a first stage circuit 10, a second stage circuit 11, and a power level detection circuit 12. The first stage circuit 10 operates in a first power domain and receives a supply voltage VDD1. The second stage circuit 11 operates in a second power domain that is different from the first power domain and receives a supply voltage VDD2. Both the first stage circuit 10 and the second stage circuit 11 are coupled to a common ground VSS.

The first stage circuit 10 receives an input signal SIN and performs a predetermined operation to generate an intermediate signal S10. The second stage circuit 11 receives the intermediate signal S10 and performs another predetermined operation to generate an output signal SOUT. The power level detection circuit 12 receives the supply voltages VDD1 and VDD2 and generates a detection signal ISO at an output terminal T12 of the power level detection circuit 12 according to the supply voltages VDD1 and VDD2. The detection signal ISO is utilized for indicating a variation of level of the supply voltage VDD1.

In a case where the supply voltage VDD2 is in an on state (that is, the level of the supply voltage VDD2 is on a predetermined high level), when the supply voltage VDD1 is in an off state (that is, the level of the supply voltage VDD1 is on a predetermined low level), the power level detection circuit 12 generates the detection signal ISO to cause the second stage circuit 11 to enter an isolation mode, thereby presenting a large crowbar current (that is, a short circuit current) between the power terminal of the supply voltage VDD2 and the common ground VSS. When the supply voltage VDD1 is switched to an on state (that is, the level of the supply voltage VDD1 is on a predetermined high level) from the off state, the power level detection circuit 12 generates the detection signal ISO to cause the second stage circuit 11 to enter a normal mode and perform the corresponding predetermined operation.

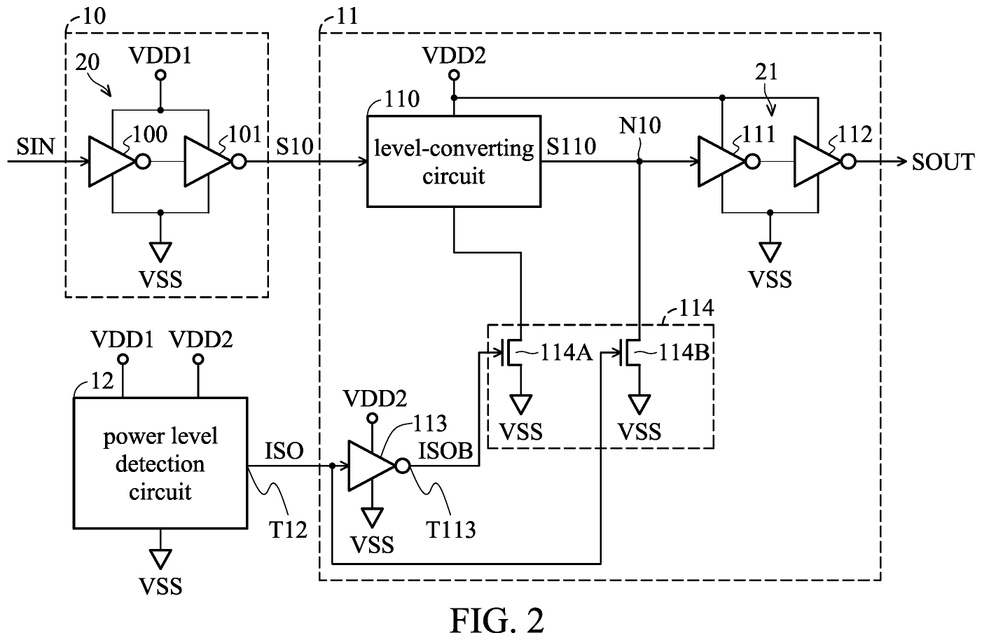

FIG. 2 shows another exemplary embodiment of the two-stage power domain circuit. In the embodiment of FIG. 2, the two-stage power domain circuit (such as, the two-stage power domain circuit 1 in FIG. 1) operates as a level shifter. Referring to FIG. 2, the first stage circuit 10 comprises an input buffer 20 that receives the input signal SIN. In some embodiments, the input buffer 20 comprises inverters 100 and 101 coupled in series between the input terminal and the output terminal of the input buffer 20. Each of the inverters 100 and 101 is coupled to the common ground VSS and further receives the supply voltage VDD1. Based on the structure of the first stage circuit 10, the predetermined operation performed by the first stage circuit 10 is a buffering operation. The input buffer 20 performs the buffering operation on the input signal SIN to generate the intermediate signal S10.

The second stage circuit 11 comprises a level-converting circuit 110 (also called main circuit), an inverter 113, an isolation circuit 114, and an output buffer 21. In some embodiments, the predetermined operation performed by the second stage circuit 11 is a level converting operation. The level-converting circuit 110 receives the intermediate signal S10 and the supply voltage VDD2 and performs the level converting operation on the intermediate signal S10 according to the supply voltage VDD2 to generate a signal S110. The output buffer 21 is coupled to the level-converting circuit 110 at a node N10. The output buffer 21 comprises inverters 111 and 112 coupled in series between the input terminal (coupled to the node N10) and the output terminal of the output buffer 21. Each of the inverters 111 and 112 is coupled to the common ground VSS and further receives the supply voltage VDD2. The output buffer 21 performs a buffering operation on the signal S110 to generate the output signal SOUT.

The inverter 113 is coupled to the common ground VSS and further receives the supply voltage VDD2. The inverter 113 receives the detection signal ISO generated by the power level detection circuit 12. The inverter 113 inverts the phase of the detection signal IOS to generate another detection signal ISOB at an output terminal T113. In the embodiment, the inverter 113 is deployed in the second stage circuit 11. However, in other embodiments, the inverter 113 may be deployed in the power level detection circuit 12 or any other suitable circuit. In these embodiment, the output terminal T113 serves as another output terminal of the power level detection circuit 12.

The isolation circuit 114 comprises N-type metal-oxide-semiconductor (NMOS) transistors 114A and 114B. The drain of the NMOS transistor 114A is coupled to the level-converting circuit 110, the source thereof is coupled to the common ground VSS, and the gate thereof receives the detection signal ISOB. The drain of the NMOS transistor 114B is coupled to the node N10, the source thereof is coupled to the common ground VSS, and the gate thereof receives the detection signal ISO. The turned-on/turned-off states of the NMOS transistors 114A and 114B are controlled by the detection signals ISOB and ISO respectively.

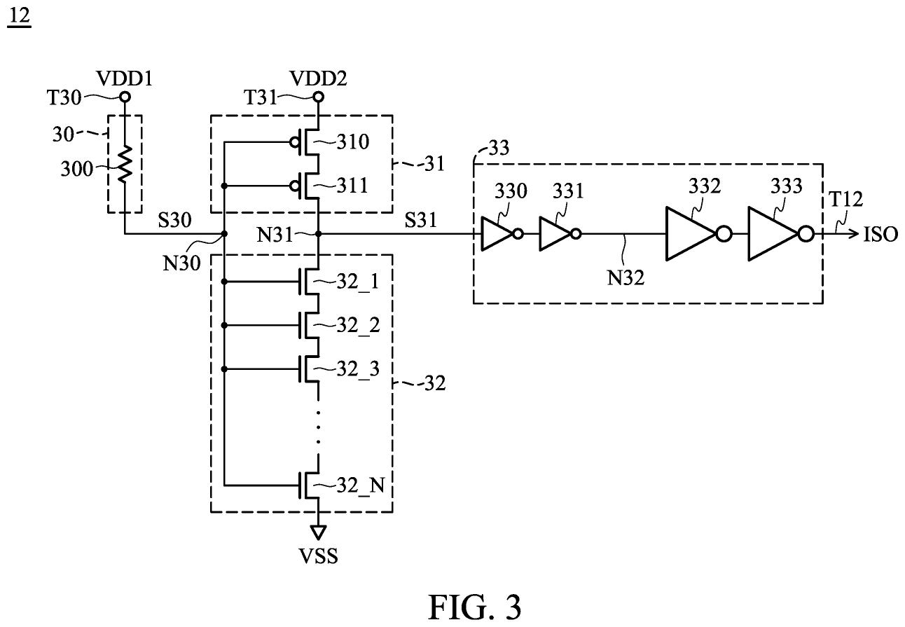

FIG. 3 shows an exemplary embodiment of the power level detection circuit 12. Referring to FIG. 3, the power level detection circuit 12 comprises a resistive circuit 30, a pull-up circuit 31, a pull-down circuit 32, and a delay chain circuit 33. In some embodiments, the resistive circuit 30 comprises a resistor R30. One terminal of the resistor R30 is coupled to a power terminal T30 to receive the supply voltage VDD1, and the other terminal thereof is coupled to a node N30. The examples of resistor R30 comprise but not limited to poly resistor, diffusion resistor, metal resistor, or Hi-R resistor, etc.

The pull-up circuit 31 is coupled between a power terminal T31 and a node N31. The pull-up circuit 31 receives the supply voltage VDD2 through the power terminal T31. The pull-up circuit 31 comprises a plurality of P-type metal-oxide-semiconductor (PMOS) transistors. In some embodiments, the pull-up circuit 31 comprising two PMOS transistors 310 and 311 is taken as an example. The PMOS transistors 310 and 311 are coupled in series between the power terminal T31 and the node N31. The gates of the PMOS transistors 310 and 311 are coupled to the node N30.

The pull-down circuit 32 is coupled between the node N31 and the common ground VSS. The pull-down circuit 32 comprises a plurality of NMOS transistors 32_1-32_N, wherein N is an integer. The NMOS transistors 32_1-32_N are coupled in series between the node N31 and the common ground VSS. The gates of the NMOS transistors 32_1-32_N are coupled to the node N30. In an embodiment, the number of PMOS transistors of the pull-up circuit 31 is less than the number of NMOS transistors of the pull-down circuit 32.

The input terminal of the delay chain circuit 33 is coupled to the node N31, and the output terminal thereof is coupled to the output terminal T12 of the power level detection circuit 12. The delay chain circuit 33 is configured to output the detection signal ISO. The delay chain circuit 33 comprises a plurality of inverters for generating the detection signal ISO according to the voltage signal S31 at the node N31. In some embodiments, the number of inverters in the delay chain circuit 33 is an even value. Referring to FIG. 3, the delay chain circuit 33 comprises four inverters, including two weak inverters 330 and 331 and two strong inverters 332 and 333. The weak inverters 330 and 331 are coupled in series between the node N31 and the node N32. The strong inverters 332 and 333 are coupled in series between the node N32 and the output terminal of the delay chain circuit 33, that is, the strong inverters 332 and 333 are coupled in series between the node N32 and the output terminal T32 of the power level detection circuit 12. In some embodiments, delay chain circuit 33 isn't necessary, and the output terminal is coupled to the node N31 directly.

In the following paragraphs, the operation of the power level detection circuit 12 is described by referring to FIGS. 2-4.

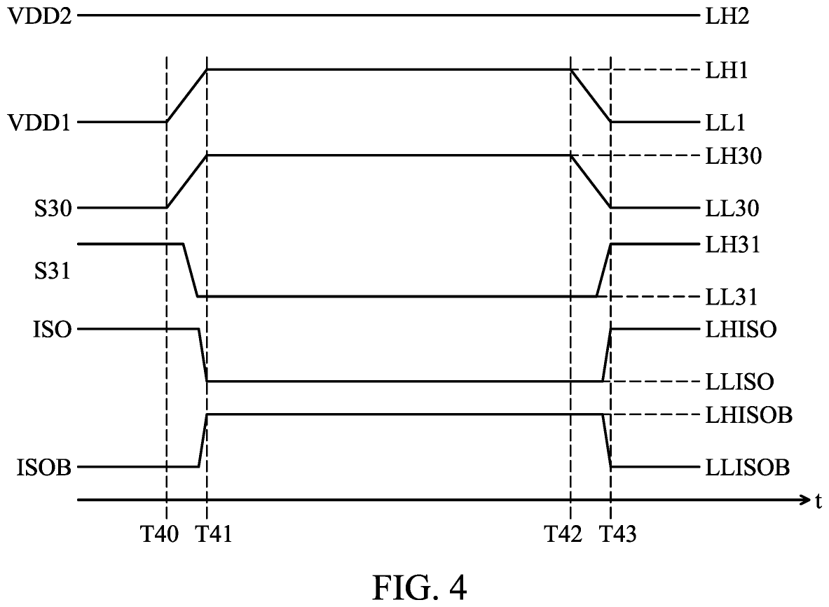

Assume that the supply voltage VDD2 is in an on state (that is, the level of the supply voltage VDD2 is on a predetermined high level LH2). Before the time point T40 shown in FIG. 4, the supply voltage VDD1 is in an off state (that is, the level of the supply voltage VDD1 is on a predetermined low level LL1). The voltage signal S30 at the node N30 is on a low level LL30 in response to the off state of the supply voltage VDD1. According to the voltage signal S30 with the low level LL30, the PMOS transistors 310 and 311 are turned on. The voltage signal S31 at the node N31 is on a high level LH31 according to the supply voltage VDD2 with the high level LH2. The inverters 330-333 of the delay chain circuit 33 receive the voltage signal S31 and delay the voltage signal S31 to make the detection signal ISO with a high level LHISO.

Referring to FIG. 2, the inverter 113 of the second stage circuit 11 inverts the phase of the detection signal ISO to make the detection signal ISOB with a low level LLISOB. The NMOS transistor 114A is turned off according to the detection signal ISOB with the low level LLISOB, and the NMOS transistor 114B is turned on according to the detection signal ISO with the high level LHISO. At this time, the second stage circuit 11 enters the isolation mode. Since the NMOS transistor 114A is turned off, the level-converting circuit 110 is isolated from the common ground VSS. Thus, no current path between the power terminal of the supply voltage VDD2 and the common ground VSS, thereby decreasing or eliminating crowbar current in the level-converting circuit 110. Moreover, the NMOS transistor 114B is turned on, and the node N10 is pull down to the common ground VSS, thereby decreasing or eliminating crowbar currents in the inverters 111 and 112.

At the time point T40, the supply voltage VDD1 starts increasing gradually. In response to the increased supply voltage VDD1, the voltage signal S30 increases gradually from the low level LL30. According to the increased voltage signal S30, the NMOS transistors 32_1-32_N are turned on, and the voltage signal S31 decreases gradually from the high level LH31. The inverters 330-333 of the delay chain circuit 33 receive the voltage signal S31 and delay the voltage signal S31 to make the detection signal ISO decrease gradually from the high level LHISO.

In some embodiments, the time point (also referred to as a transition time point) when the detection signal ISO starts decreasing from the high level LHISO (that is, the time point that the detection signal ISO starts transition from the high level LHISO to the low level LHISO) is controlled by the ratio of the number of PMOS transistors of the pull-up circuit 31 to the number of NMOS transistors of the pull-down circuit 32 and further controlled by the operation characteristics of the weak inverters 330 and 331. In some embodiments, the lower ratio means the transition time point is later. In some embodiments, the above ratio and the operation characteristics of the weak inverters 330 and 331 are designed to cause the detection signal ISO to start decreasing from the high level LHISO after the supply voltage VDD1 increases from the low level LL1 to a half of the level difference between the high level LH1 and the low level LL1, this is only for illustrative purposes, and the present invention is not limited thereto. In some embodiments, the decreasing slope of the detection signal ISO is adjusted according to the operation characteristics of the strong inverters 332 and 333. In this disclosure, the decreasing slope and increasing slope is collectively called transition slope. In other words, the strong inverters 332 and 333 are configured to adjust the transition slop of the detection signal ISO.

Referring to FIG. 2, the inverter 113 inverts the phase of the detection signal ISO to generate the detection signal ISOB. When the detection signal ISO starts to decrease from the high level LHISO to the low level LLISO, the detection signal ISOB starts to increase gradually from the low level LLISOB to the high level LHISOB. The NMOS transistor 114A is turned on according to the increased detection signal ISOB, and the NMOS transistor 114B is turned off according to the decreased detection signal ISO. Thus, the level-converting circuit 110 and the output buffer 21 operate normally. In other words, the second stage circuit 11 enters the normal mode so that the second stage circuit 11 performs the level converting operation.

As described above, in some embodiments, the detection signal ISO starts decreasing from the high level LHISO after the supply voltage VDD1 increases from the low level LL1 to a half of the level difference between the high level LH1 and the low level LL1, which may ensure that the second stage circuit 11 enters the normal mode after the intermediate signal S10 is stable (for example, reach to a predetermined high level or a predetermined low level), thereby decreasing or eliminating crowbar current in the second stage circuit 11.

In some embodiments, the ratio of number of PMOS transistors of the pull-up circuit 31 to the number of NMOS transistors of the pull-down circuit 32 and the operation characteristics of the weak inverters 330 and 331 are designed or adjusted to delay the time point that the detection signal ISO starts decreasing (that is, transition) from the high level LHISO to the low level LLISO (or the time point that the detection signal ISOB starts increasing (that is, transition) from the low level LLISOB to the high level LHISOB), in order to ensure that the NMOS transistor 114A is fully turned on after the intermediate signal S10 is stable, thereby decreasing or eliminating crowbar current in the second stage circuit 11. Furthermore, in some embodiments, the operation characteristics of the strong inverters 332 and 333 are designed to make the decreasing slope of the detection signal ISO (or the increasing slope of the detection signal ISOB) fast enough, thereby further decreasing or eliminating crowbar current in the second stage circuit 11.

Referring to FIG. 4, at the time point T41, the supply voltage VDD1 reaches a high level LH1. In response to the supply voltage VDD1 with the high level LH1, the detection signal ISO reaches to a low level LLISO based on the operation of the power level detection circuit 12. The detection signal ISOB reaches a high level LHISOB. Thus, the NMOS transistor 114A is still turned on, and the NMOS transistor 114B is still turned off. Thus, the second stage circuit 11 is continuously in the normal mode.

At the time point T42, the supply voltage VDD1 starts decreasing gradually. In response to the decreased supply voltage VDD1, the voltage signal S30 decreases gradually from the high level LH30. According to the decreased voltage signal S30, the PMOS transistors 310 and 320 are turned on, and the voltage signal S31 increases gradually from the low level LL31. The inverters 330-333 of the delay chain circuit 33 receive the voltage signal S31 and delay the voltage signal S31 to make the detection signal ISO increase gradually from the low level LLISO.

In some embodiments, the time point (also referred to as a transition time point) when the detection signal ISO starts increasing (that is, transition) from the low level LLISO is controlled by the ratio of the number of number of PMOS transistors of the pull-up circuit 31 to the number of NMOS transistors of the pull-down circuit 32 and further controlled by the operation characteristics of the weak inverters 330 and 331. In some embodiments, the above ratio and the operation characteristics of the weak inverters 330 and 331 are designed to cause the detection signal ISO to start increasing from the low level LLISO after the supply voltage VDD1 decreases from the high level LH1 to a half of the level difference between the high level LH1 and the low level LL1, this is only for illustrative purposes, and the present invention is not limited thereto. In some embodiments, the increasing slope of the detection signal ISO is adjusted according to the operation characteristics of the strong inverters 332 and 333.

Referring to FIG. 2, the inverter 113 inverts the phase of the detection signal ISO to generate the detection signal ISOB. When the detection signal ISO starts to increase from the low level LLISO to the high level LHISO, the detection signal ISOB starts to decrease gradually from the high level LHISOB to the low level LLISOB. The NMOS transistor 114A is turned off according to the decreased detection signal ISOB, and the NMOS transistor 114B is turned on according to the increased detection signal ISO. then, the second stage circuit 11 enters the isolation mode.

As described above, in some embodiments, the detection signal ISO starts increasing from the low level LHISO after the supply voltage VDD1 decreases from the high level LH1 to a half of the level difference between the high level LH1 and the low level LL1, which may ensure that the second stage circuit 11 enters isolation mode after the intermediate signal S10 is stable (for example, reach to a predetermined high level or a predetermined low level), thereby decreasing or eliminating crowbar current in the second stage circuit 11.

In some embodiments, the ratio of the number of PMOS transistors of the pull-up circuit 31 to the number of NMOS transistors of the pull-down circuit 32 and the operation characteristics of the weak inverters 330 and 331 are designed or adjusted to delay the time point that the detection signal ISO starts increasing (that is, transition) from the low level LLISO to the high level LHISO (or the time point that the detection signal ISOB starts decreasing (that is, transition) from the high level LHISOB to the low level LLISOB), in order to ensure that the NMOS transistor 114A is fully turned off after the intermediate signal S10 is stable, thereby decreasing or eliminating crowbar current in the second stage circuit 11. Furthermore, in some embodiments, the operation characteristics of the strong inverters 332 and 333 are designed to make the increasing slope of the detection signal ISO (or the decreasing slope of the detection signal ISOB) fast enough, thereby further decreasing or eliminating crowbar current in the second stage circuit 11.

Referring to FIG. 4, at the time point T43, the supply voltage VDD1 reaches the low level LL1. In response to the supply voltage VDD1 with the low level LL1, the detection signal ISO reaches to the high level LHISO based on the operation of the power level detection circuit 12. The detection signal ISOB reaches the low level LLISOB. Thus, the NMOS transistor 114A is still turned off, and the NMOS transistor 114B is still turned on. Thus, the second stage circuit 11 is continuously in the isolation mode.

According to the above embodiments, the power level detection circuit 12 controls the second stage circuit 11 of the second power domain enters a normal mode or an isolation mode according to the variation of the supply voltage VDD1 of the first power domain, thereby decreasing or eliminating crowbar currents in the second stage circuit 11.

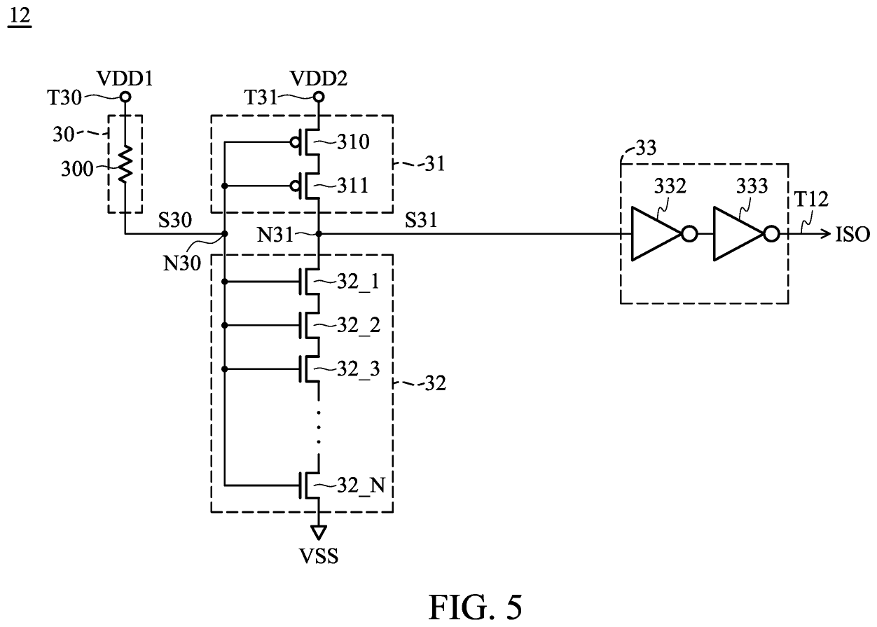

In the embodiment of FIG. 3, the delay chain circuit 33 comprises two weak inverters 330 and 331, and two strong inverters 332 and 333. In another embodiment, the delay chain circuit 33 comprises only strong inverters without any weak inverters. As shown in FIG. 5, the delay chain circuit 33 comprises two strong inverters 332 and 333 without any weak inverters.

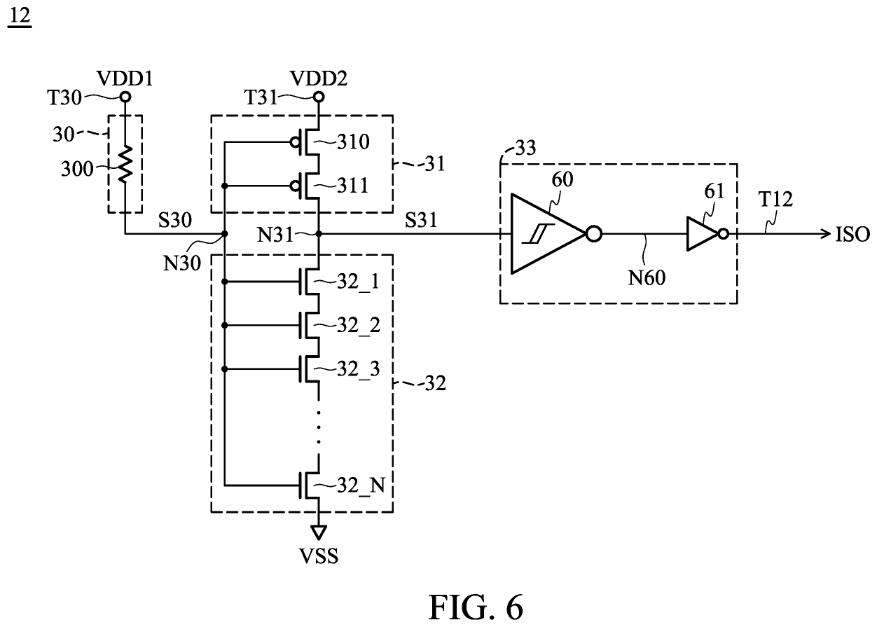

In another embodiment, the delay chain circuit 33 comprises a Schmitt trigger and at least one strong inverter. In this embodiment, the number of strong inverters is an odd value. Referring to FIG. 6, the delay chain circuit 33 comprises a Schmitt trigger 60 and a strong inverter 61. The Schmitt trigger 60 may delay the transition time point of the detection signal ISO/ISOB (that is, the time point that the detection signal ISO/ISOB starts transition from a high level to a low level or from a low level to a high level). Moreover, the Schmitt trigger 60 may filter the glitch on the voltage signal S31 that is induced by the glitch on the supply voltage VDD1.

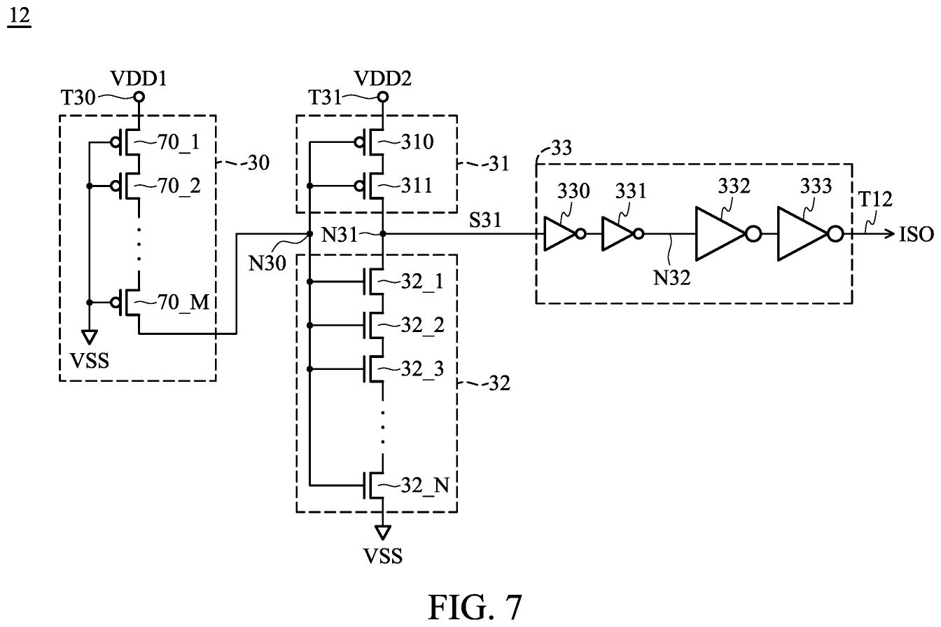

In the embodiment of FIG. 3, the resistive circuit 30 comprises a resistor R30. In another embodiment, as shown in FIG. 7, the resistive circuit 30 comprises a plurality of PMOS transistors 70_1-70_M coupled in series between the power terminal T30 and the node N30, wherein M is an integer. The gates of the PMOS transistors 70_1-70_M are coupled to the common ground VSS. Thus, the PMOS transistors 70_1-70_M are always turned on, which provides resistance.

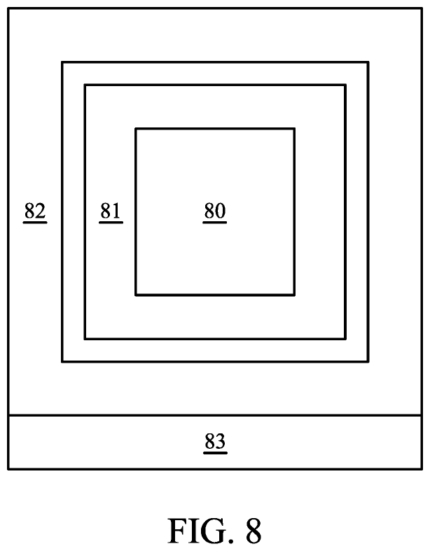

In some embodiments, the power level detection circuit 12 is implemented by a standard cell structure. FIG. 8 shows an exemplary embodiment of layout of a power level detection circuit. Referring to FIG. 8, a standard cell 8 comprises regions 80-82 and a bottom region 83. The resistive circuit 30 is formed in the region 80. The region 80 is surrounded by a region 81 where a guard ring is formed. The region 81 is surrounded by a region 82 where filter cells and/or boundary cells are formed. The PMOSs of the pull-up circuit 31, the NMOS transistors of the pull-down circuit 32, and the delay chain circuit 33 are formed in the bottom region 83.

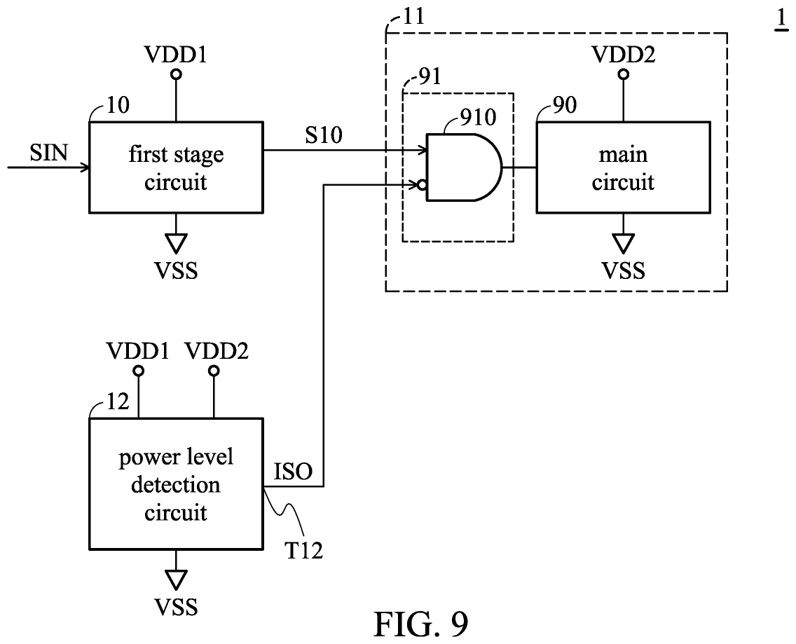

FIG. 9 shows another exemplary embodiment of the two-stage power domain circuit 1. Referring to FIG. 9, the second stage circuit 11 comprises a main circuit 90 and an isolation circuit 91. The main circuit 90 receives the supply voltage VDD2 and performs a predetermined operation according to the intermediate signal S10 to generate the output signal SOUT. The isolation circuit 91 is coupled between the first stage circuit 10 and the main circuit 90. The isolation circuit 91 receives the intermediate signal S10 and the detection signal ISO. The isolation circuit 91 determines whether the intermediate signal S10 is transmitted to the main circuit 90 according to the detection signal ISO.

In some embodiments, the isolation circuit 91 comprises an AND logic gate 910 that has a non-inverting input terminal receiving the intermediate signal S10, an inverting input terminal receiving the detection signal ISO, and an output terminal coupled to the main circuit 90. When the power level detection circuit 12 generates the detection signa ISO with the high level LHISO, the second stage circuit 11 enters the isolation mode. In details, according to the operation of the AND logic gate 910, the output signal of the AND logic gate 910 is not varied with the intermediate signal S10. That is, the main circuit 90 is isolated from the first stage circuit 10, and the intermediate signal S10 is not transmitted to the main circuit 90. Thereby decreasing or eliminating crowbar currents in the second stage circuit 11. When the power level detection circuit 12 generates the detection signa ISO with the low level LLISO, the second stage circuit 11 enters the normal mode. In details, according to the operation of the AND logic gate 910, the output signal of the AND logic gate 910 varies with the intermediate signal S10, that is, the intermediate signal S10 is transmitted to the main circuit 90, and the main circuit 90 normally operates to perform the predetermined operation according to the intermediate signal S10. Thereby decreasing or eliminating crowbar currents in the second stage circuit 11. In this embodiment, AND logic gate 910 is only used for illustration purpose, in other embodiments it could be replaced by other logic circuits. The operations of the power level detection circuit 12 in this embodiment are described above, for the sake of simplicity, further elaboration is omitted here.

While the present disclosure has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A power level detection circuit comprising:
a resistive circuit, coupled between a first power terminal and a first node, wherein the first power terminal is coupled to a first supply voltage;
a pull-up circuit, coupled between a second power terminal and a second node, wherein the second power terminal is coupled to a second supply voltage;
a pull-down circuit, coupled between the second node and a common ground; and
an output terminal, coupled to the second node, and configured to output a detection signal,
wherein the pull-up circuit and the pull-down circuit are configured to control a time point that the detection signal starts to transition from a first level to a second level according to the first supply voltage and the second supply voltage.

2. The power level detection circuit as claimed in claim 1, further comprising:
a delay chain circuit coupled between the second node and the output terminal, comprising at least one strong inverter,
wherein the at least one strong inverter is configured to adjust a transition slop of the detection signal.

3. The power level detection circuit as claimed in claim 2, wherein the at least one strong inverter is further configured to increase the transition slop of the detection signal.

4. The power level detection circuit as claimed in claim 2, wherein the delay chain circuit further comprises:
at least one weak inverter coupled between the second node and the at least one strong inverter, configured to control the time point that the detection signal starts to transition from the first level to the second level together with the pull-up circuit and the pull-down circuit.

5. The power level detection circuit as claimed in claim 4, wherein the at least one weak inverter, the pull-up circuit and the pull-down circuit are configured to delay the time point that the detection signal starts to transition from the first level to the second level.

6. The power level detection circuit as claimed in claim 2, wherein the delay chain circuit further comprises:
a Schmitt trigger coupled between the second node and the at least one strong inverter, configured to control the time point that the detection signal starts to transition from the first level to the second level together with the pull-up circuit and the pull-down circuit.

7. The power level detection circuit as claimed in claim 6, wherein the Schmitt trigger, the pull-up circuit and the pull-down circuit are configured to delay the time point that the detection signal starts to transition from the first level to the second level.

8. The power level detection circuit as claimed in claim 1, wherein the pull-up circuit comprises:
a plurality of P-type metal-oxide-semiconductor (PMOS) transistors coupled in series between the second power terminal and the second node,
wherein gates of the plurality of PMOS transistors are coupled to the first node, and
wherein the pull-down circuit comprises:
a plurality of N-type metal-oxide-semiconductor (MOS) transistors coupled in series between the second node and the common ground,
wherein gates of the plurality of NMOS transistors are coupled to the first node, and
wherein a ratio of the number of plurality of PMOS transistors of the pull-up circuit to the number of plurality of NMOS transistors of the pull-down circuit is configured to delay the time point that the detection signal starts transition from the first level to the second level.

9. The power level detection circuit as claimed in claim 1, wherein the output terminal is a first output terminal, and the detection signal is a first detection signal, wherein the power level detection circuit further comprises:
a second output terminal, configured to output a second detection signal; and
an inverter, coupled between the second node and the second output terminal, and configured to output the second detection signal.

10. The power level detection circuit as claimed in claim 1, wherein the power level detection circuit is implemented by a standard cell structure.

11. A two-stage power domain circuit comprises:
a first stage circuit operating in a first power domain, configured to receive an input signal and generate an intermediate signal;
a second stage circuit operating in a second power domain, configured to receive the intermediate signal and generate an output signal; and
a power level detection circuit, configured to receive a first supply voltage of the first power domain and a second supply voltage of the second power domain, and to generate a first detection signal and control a time point that the first detection signal starts to transition from a first level to a second level according to the first supply voltage and the second supply voltage.

12. The two-stage power domain circuit as claimed in claim 11, wherein the second stage circuit comprises:
a main circuit, configured to receive the second supply voltage and the intermediate signal and perform a predetermined operation according to the intermediate signal to generate a first signal at a first node;
an output buffer, configured to receive the first signal and generate the output signal; and
an isolation circuit, configured to receive the first detection signal and a second detection signal inverse to the first detection signal, and to control whether a first path between the main circuit and a common ground is cut off according to the second detection signal, and to control whether a second path between the first node and the common ground is cut off according to the first detection signal.

13. The two-stage power domain circuit as claimed in claim 12, wherein the second stage circuit further comprises:
an inverter, coupled between the power level detection circuit and the isolation circuit, and configured to output the second detection signal according to the first detection signal.

14. The two-stage power domain circuit as claimed in claim 12, wherein the isolation circuit comprises:
a first transistor having a first terminal coupled to the level-converting circuit, a second terminal coupled to the common ground, and a third terminal configured to receive the second detection signal; and
a second transistor having a first terminal coupled to the first node, a second terminal coupled to the common ground, and a third terminal configured to receive the first detection signal.

15. The two-stage power domain circuit as claimed in claim 11, wherein the second stage circuit further comprises:
a main circuit, configured to receive the second supply voltage and perform a predetermined operation according to the intermediate signal to generate the output signal; and
an isolation circuit, coupled between the first stage circuit and the main circuit, configured to receive the intermediate signal and the first detection signal,
wherein the isolation circuit is further configured to determine whether the intermediate signal is transmitted to the main circuit according to the first detection signal.

16. The two-stage power domain circuit as claimed in claim 15, wherein the isolation circuit comprises:
an AND logic gate having a non-inverting input terminal configured to receive the intermediate signal, an inverting input terminal configured to receive the first detection signal, and an output terminal coupled to the main circuit.

17. The two-stage power domain circuit as claimed in claim 11, wherein the power level detection circuit comprises:
a resistive circuit coupled between a first power terminal and a first node, wherein the first terminal receives the first supply voltage;
a pull-up circuit coupled between a second power terminal and a second node, wherein the second power terminal receives the second supply voltage;
a pull-down circuit coupled between the second node and a common ground; and
an output terminal, coupled to the second node, configured to output the first detection signal,
wherein the pull-up circuit and the pull-down circuit are configured to control the time point that the first detection signal starts to transition from the first level to the second level.

18. The two-stage power domain circuit as claimed in claim 17, wherein the power level detection circuit further comprises:
a delay chain circuit, coupled between the second node and the output terminal, comprising at least one strong inverter, wherein the at least one strong inverter is configured to adjust a transition slop of the detection signal.

19. The two-stage power domain circuit as claimed in claim 18, wherein the delay chain circuit further comprises:
at least one weak inverter coupled between the second node and the at least one strong inverter, configured to control the time point that the first detection signal starts to transition from the first level to the second level together with the pull-up circuit and the pull-down circuit.

20. The two-stage power domain circuit as claimed in claim 18, wherein the delay chain circuit further comprises:
a Schmitt trigger coupled between the second node and the at least one strong inverter, configured to control the time point that the first detection signal starts to transition from the first level to the second level together with the pull-up circuit and the pull-down circuit.
